(19) United States
(12) Patent Application Publication
(10) Pub. No.: US 2010/0264949 A1
(43) Pub. Date: Oct. 21, 2010

(54) FLEXURE BAND AND USE THEREOF IN A PROBE CARD ASSEMBLY

(75) Inventor: Eric D. Hobbs, Livermore, CA (US)

Correspondence Address: N. KENNETH BURRASTON;KIRTON & MCCONKIE, P.O. BOX 45120, SALT LAKE CITY, UT, 84145-0120, US

(73) Assignee: FORMFACTOR, INC.

(21) Appl. No.: 12/423,927

(22) Filed: Apr. 15, 2009

(51) Int. Cl. G01R 31/02; G01R 1/073

(52) U.S. Cl. 324/760; 324/754

(57) ABSTRACT

A flexure band can comprise structures configured to have elastic properties. Such a band can be stretched but will return generally to its original shape after forces that stretched the band are removed. The flexure band can hold one or more temperature control devices against a peripheral edge of a stiffening frame in a probe card assembly, or the flexure band can itself be a temperature control device. The band can be made of a metal that can be selected to impart one or more of the following properties: low thermal conductivity, high specific heat, generates little to no appreciable contamination, and/or usable over a wide range of temperatures. A material can be added to the band as a full or partial coating that enhances or adds one or more of the above-mentioned possible properties of the metal band.

### BACKGROUND

Probe card assemblies and other types of contactor devices are used to contact and test electronic devices. Some such electronic devices, such as semiconductor dies, are tested in a relatively clean environment. The present invention is directed to a flexure band that can be used with such probe card assemblies or other types of contactor devices. The flexure band can also be used in other applications such as in medical devices or electronic products.

### SUMMARY

In some embodiments, a probe card assembly can include a signal interface, conductive probes, a support assembly, a temperature control device, and a flexure band. The signal interface can be configured to connect to a test controller for controlling testing of semiconductor dies, and the conductive probes, which can be electrically connected to the signal interface, can be configured to contact terminals of the semiconductor dies. The signal interface and probes can be disposed on the support assembly. The temperature control device can be disposed at a peripheral edge of a component of the support assembly, and a flexure band can be stretched around the peripheral edge of the component of the support assembly.

In some embodiments, a method of producing a tested semiconductor die can include obtaining a probe card assembly, which can include a support assembly, electrically conductive probes, and a flexure band. A signal interface to a test controller for controlling testing of semiconductor dies and the probes can be disposed on the support assembly. The probes can be configured to contact terminals of the semiconductor dies, and the probes can be electrically connected through the probe card assembly to the interface. The flexure band can be stretched around a peripheral edge of a component of the support assembly, and can hold a temperature control device against the peripheral edge. The method can further include controlling a temperature control device, and effecting contact between the probes and terminals of the dies. The method can also include testing the dies by providing test signals between the terminals and the probes through the probe card assembly.

In some embodiments, a flexure band can include elastic metal structures disposed in an interconnected continuous loop forming a band with an outer face and an inner face.

### BRIEF DESCRIPTION OF THE DRAWINGS

FIGS. 1A, 1B, and 1C illustrate an example of a contactor device with a flexure band according to some embodiments of the invention.

FIG. 2 illustrates an example of a flexure band with a continuous flexure section around the band according to some embodiments of the invention.

FIG. 3 illustrates an example of a flexure band with alternating flexure sections and inflexible sections according to some embodiments of the invention.

FIG. 4 illustrates an example of a flexure band comprising pieces that are coupled one to another according to some embodiments of the invention.

FIG. 5 illustrates a cross-sectional view of a flexure band with a material that is thermally insulating according to some embodiments of the invention.

FIG. 6A illustrates an example of a pattern of the flexure structure of the band of FIG. 2, FIG. 3, or FIG. 4 according to some embodiments of the invention.

FIGS. 7A, 7B, and 7C illustrate an example of a probe card assembly with a flexure band stretched around a peripheral edge of a component of the probe card assembly according to some embodiments of the invention.

FIG. 8 illustrates an example of a test system in which the probe card assembly of FIGS. 7A, 7B, and 7C can be used to test electronic devices according to some embodiments of the invention.

FIG. 9 illustrates an example of a process for testing electronic devices according to some embodiments of the invention.

### DETAILED DESCRIPTION OF EXEMPLARY EMBODIMENTS

This specification describes exemplary embodiments and applications of the invention. The invention, however, is not limited to these exemplary embodiments and applications or to the manner in which the exemplary embodiments and applications operate or are described herein. Moreover, the Figures may show simplified or partial views, and the dimensions of elements in the Figures may be exaggerated or otherwise not in proportion for clarity. In addition, as the terms “on,” “attached to,” or “coupled to” are used herein, one object (e.g., a material, a layer, a substrate, etc.) can be “on,” “attached to,” or “coupled to” another object regardless of whether the one object is directly on, attached, or coupled to the other object or there are one or more intervening objects between the one object and the other object. Also, directions (e.g., above, below, top, bottom, side, up, down, under, over, upper, lower, horizontal, vertical, “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

In some embodiments of the invention, a flexure band can be provided. The band can include structures configured to have elastic properties. For example, the band can be stretched but will return generally to its original shape after forces that stretched the band are removed. Moreover, the band can be made of a metal that can be selected to impart one or more of the following properties: low thermal conductivity, high specific heat, generates little to no appreciable contamination, and/or usable over a wide range of temperatures. Non-limiting examples of suitable metals include stainless steel, brass, and beryllium-copper. In some embodiments, a material can be added to the band as a full or partial coating that enhances or adds one or more of the above-mentioned possible properties of the metal band. Non-limiting examples of suitable coatings include polymer materials (e.g., fluoropolymers), electroplated materials (e.g., nickel), and ceramic materials. Nickel can reduce the tendency to rust, which can reduce the tendency to give off contamination. In some embodiments, the flexure band can hold one or more temperature control devices and/or one or more temperature sensing devices against a peripheral edge of a stiffening frame in a probe card assembly. In other embodiments, the flexure band itself can be configured to be a temperature control device and/or a temperature sensing device.

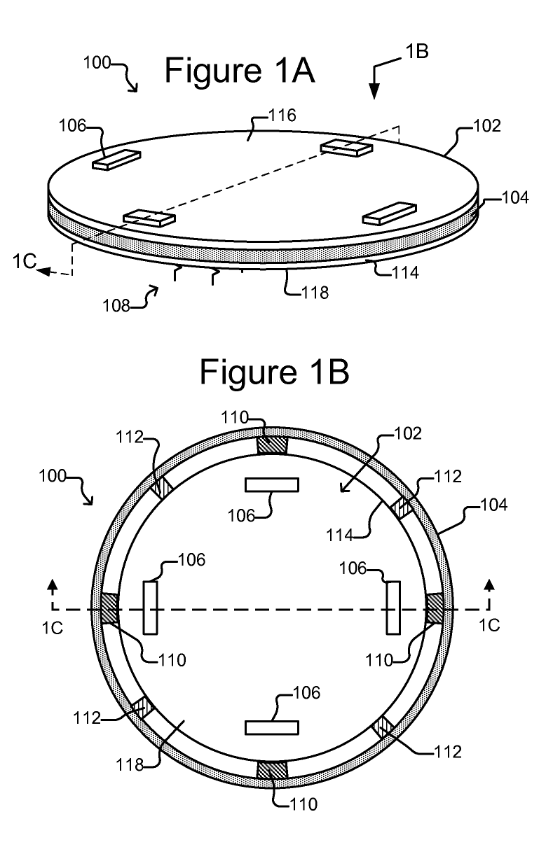

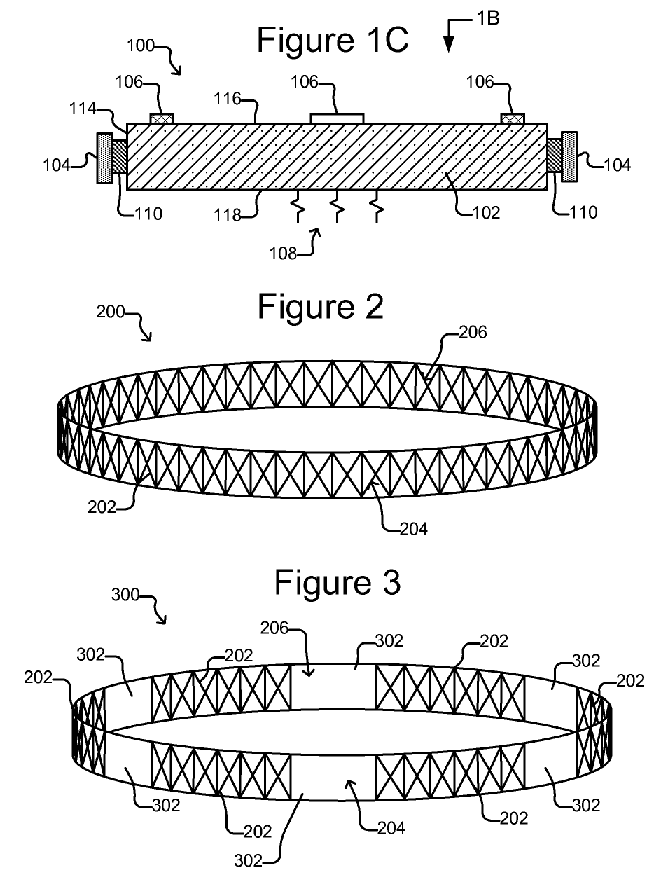

FIGS. 1A, 1B, and 1C show an example of a contactor device 100 that includes a flexure band 104 disposed about a peripheral edge 114 of a component of the contactor device 100 according to some embodiments of the invention. As shown, the contactor device 100 can include a support assembly 102. Signal connectors 106 can be on a first surface 116 of the support assembly 102, and electrically conductive probes 108 can be on a second surface 118 of the support assembly 102. (Signal connectors 106 can be a non-limiting example of a signal interface.) As shown in FIG. 1A, the peripheral edge 114 can connect the first surface 116 to the second surface 118. The probes 108 can be spring probes suitable for making pressure based electrical connections by being pressed against terminals of an electronic device (not shown) to be tested. Alternatively, the probes 108 can be other types of probes including posts, bumps. etc. The signal connectors 106 can be any connection device suitable for making a plurality of signal connections with a test controller (not shown) for controlling testing of the electronic device (not shown) to be tested. For example, the signal connectors 106 can be electrical connectors such as zero-insertion-force connectors, pogo pin pads, etc. As yet other examples, the signal connectors 106 can be optical connectors, wireless interfaces, etc. Although a certain number of signal connectors 106 and probes 108 are illustrated in FIGS. 1A, 1B, and 1C, this is for purposes of illustration only, and the contactor device 100 can have other numbers of signal connectors 106 and other numbers of probes 108.

The support assembly 102 can be any structure suitable for supporting the signal connectors 106 and the probes 108 and for providing electrical connections (not shown) between the signal connectors 106 and the probes 108. For example, the support assembly 102 can be a single substrate as shown in FIGS. 1A, 1B, and 1C. For example, the support assembly 102 can be a printed circuit board or a multilayer ceramic substrate with internal wiring. In other examples, the support assembly 102 can comprise a plurality of structures coupled one to another.

As shown in FIGS. 1A, 1B, and 1C, a flexure band 104 can be disposed about a peripheral edge 114 of the support assembly 102 or a component of the support assembly 102 if the support assembly 102 comprises multiple components. The flexure band 104 can be made of metal and can be elastic so that, like a rubber band, it can be stretched and, while stretched, provides forces that oppose the stretching of the flexure band 104. The flexure band 104 can be used like a rubber band. For example, as shown in FIGS. 1A, 1B, and 1C, the flexure band 104 can be stretched and placed around the peripheral edge 114 of the support assembly 102 or a component of the support assembly 102. A circumference of the flexure band 104, in an unstretched state, can be less than a circumference of the peripheral edge 114 around which the flexure band 104 is disposed so that the flexure band 104 is in a stretched state while around the peripheral edge 114. The elasticity of the flexure band 104 can thus result in forces that hold the flexure band 104 against the peripheral edge 114. In some embodiments, the flexure band 104 can be relatively thin so that it protrudes relatively little from the peripheral edge 114. For example, in some embodiments, the flexure band 104 can be less than 3000 microns thick or even less than 1500 microns, less than 750 microns, or less than 350 microns thick. In other embodiments, however, the flexure band 104 can be more than 3000 microns thick.

As shown in FIGS. 1B and 1C, the flexure band 104 can hold elements against the peripheral edge 114. For example, the flexure band 104 can hold one or more temperature control devices 110 and/or one or more temperature sensing devices 112 against the peripheral edge 114. The flexure band 104 can thus be in a stretched state around the peripheral edge 114, and temperature control devices 110 and/or temperature sensing devices 112 can be located between the peripheral edge 114 and the flexure band 104. Although a certain number of temperature control devices 110 and a certain number of temperature sensing devices 112 are shown in FIGS. 1B and 1C, other numbers of temperature control devices 110 and/or other numbers of temperature sensing devices 112 can be located between the flexure band 104 and the peripheral edge 114. Non-limiting examples of suitable temperature control devices 110 include resistive heating devices, devices through which heated or cooled liquids or gases can be passed, and Peltier devices. Non-limiting examples of suitable temperature sensing devices 112 include thermometers, thermisters, and thermocouples.

The configuration of the contactor device 100 shown in FIGS. 1A, 1B, and 1C is an example only, and variations are possible. For example, the flexure band 104 itself can be a temperature control device and/or a temperature sensing device. For example the flexure band 104 can be a resistive heating device. In such a case, temperature control devices 112 need not be included. As another example, whether the flexure band 104 is or is not a temperature control device, temperature sensing devices 112 need not be included or the temperature sensing devices 112 can be integrated into the support assembly 102. As another example, the resistance of the flexure band 104 can be measured and changes in the measured resistance can indicate changes in the temperature of the flexure band 104. The flexure band 104 can thus itself be a temperature sensing device.

In some embodiments, the flexure band 104, in addition to the properties discussed above, can have one or more of the following properties: the forces generated by the band 104 when stretched remain substantially constant over a wide temperature range; the flexure band does not generate appreciable contamination (e.g., due to out gassing); and/or the flexure band 104 has a relatively high specific heat, low thermal conductivity, and/or a high thermal diffusivity. In some embodiments, the forces generated by the flexure band 104 when stretched can remain substantially constant even as the operating temperature change. For example, the forces generated by the flexure band 104 when stretched around the peripheral edge 114 of the support assembly 102 can remain substantially constant even as the operating temperature changes by selecting the support assembly 102 and the flexure band 104 to have approximately the same thermal strains. A non-limiting example can be selecting the support assembly 102 and the flexure band 104 to have approximately the same coefficients of thermal expansion and/or keeping the temperatures of the support assembly 102 and the flexure band 104 approximately the same. In some embodiments, the flexure band 104 can out gas no more than a negligible level of contaminates. A negligible level of a contaminate or contaminates can be a level that does not adversely affect the electronic devices (not shown) contacted by the probes 108 and being tested. The foregoing are examples only, and the invention is not limited to the foregoing.

To achieve one or more of the foregoing characteristics, in some embodiments, the flexure band 104 can comprise stainless steel, alloy 42, or kovar. In other embodiments, the flexure band 104 can comprise brass or a beryllium-copper alloy. In some embodiments, the flexure band 104 can include a coating that provides or enhances one or more of the above-discussed characteristics of the flexure band 104. For example, the flexure band can be fully or partially coated with a polymer material (e.g., a fluoropolymer), an electroplated material (e.g., nickel), and/or a ceramic material.

FIG. 2 illustrates a flexure band 200 that can be an example of the flexure band 104 of FIGS. 1A, 1B, and 1C according to some embodiments of the invention. As shown in FIG. 2, the flexure band 200 can have an outer face 204 and an inner face 206. For example, when stretched around the peripheral edge 114 of the support assembly 102 in FIGS. 1A, 1B, and 1C, the outer face 204 can face away from the peripheral edge 114 and the inner face 206 can face toward the peripheral edge 114. As also shown in FIG. 2, the flexure band 200 can comprise a plurality of interconnected flexure structures 202, which can be configured to impart elasticity to the flexure band 200. (The flexure structures 202 can be non-limiting examples of an elastic structure.) As shown in FIG. 2, the flexible structures 202 can be continuous around the circumference of the flexure band 200.

Alternatively, the flexible structures 202 need not be continuous around the circumference of the flexure band 200. FIG. 3 illustrates an example of such a flexure band 300 according to some embodiments of the invention. The flexure band 300—which can be an example of the flexure band 104 in FIGS. 1A, 1B, and 1C—can be like the flexure band 200 except that the flexure band 300 can include inflexible sections 302 between the flexure structures 202 as shown in FIG. 3. (The inflexible sections 302 can be non-limiting examples of non-elastic metal structures.) Regardless of whether the flexure structures 202 are continuous as in the flexure band 200 of FIG. 2 or are located between inflexible sections 302 as in the flexure band 300 of FIG. 3, the bands 200 and 300 can be continuous around the circumference of the band as shown in FIGS. 2 and 3.

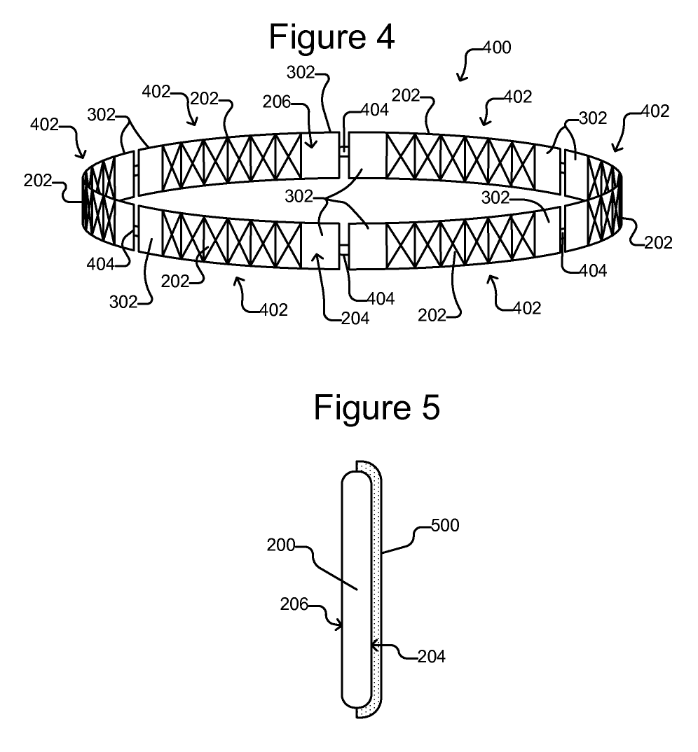

Alternatively, the bands 200 and 300 can comprises pieces that are joined together. FIG. 4 illustrates an example of such a flexure band 400 according to some embodiments of the invention. The flexure band 400—which can be an example of the flexure band 104 in FIGS. 1A, 1B, and 1C—can be like the flexure band 200 or the flexure band 300 except that the flexure band 400 can comprise pieces 402 that are joined together by joints 404 as shown in FIG. 4. Each piece 402 can comprise one or more flexure structures 202 and one or more inflexible sections 302 as shown in FIG. 4. Alternatively, each piece 402 can consist entirely of flexure structures 202. The joints 404 can be any suitable joints including without limitation clasps, hooks, latches, welds, etc.

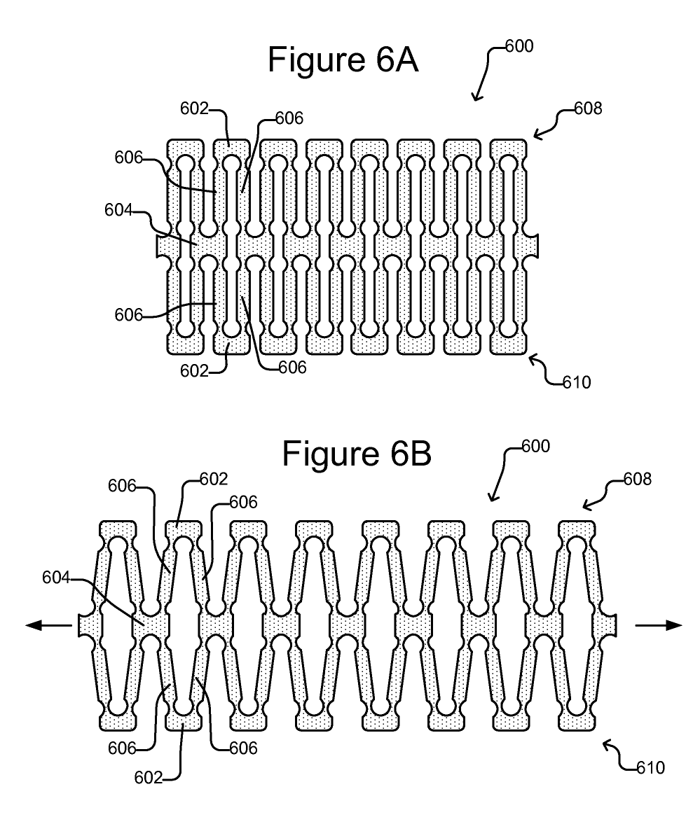

The flexure bands 200, 300, and 400 can have one or more of the properties and can be made of any of the materials discussed above with regard to the flexure band 104. As mentioned above, the flexure band 104 can include a coating that partially or fully coats the band 104. FIG. 5—which shows a simplified cross-section of the band 200 of FIG. 2—illustrates the band 200 with a coating 500. Although the coating 500 is shown in FIG. 5 coating the outer face 204 of the band 200, the coating 500 can also coat all or part of the inner face 206 of the band 200. Indeed, in some embodiments, the coating 500 can coat only the inner face 206 and not the outer face 204. Alternatively, the coating 500 can coat only part of the outer face 204, only part of the inner face 206.

The coating 500 can comprise a material selected to provide or enhance a desired property of the band 200. For example, the coating 500 can comprise a material that reduces the out gassing properties of the flexure band 200. As another example, the coating 500 can provide or enhance desired thermal properties. The coating 500 can thus comprise a thermal insulating material. As mentioned above, a non-limiting example of a material for coating 500 is a polymer material (e.g., a flouropolymer), an electroplated material (e.g., nickel), or a ceramic material. The coating 500—including any variation discussed above—can be provided on the flexure band 104, 300, or 400.

FIGS. 6A and 6B illustrate a flexure structure 600 that can be a non-limiting example of the flexure structure 202 in FIGS. 2, 3, and 4. As shown in FIG. 6A, the flexure structure 600 can comprise outer parts 602 disposed along an upper edge 608 of the flexure structure 600, outer parts 602 disposed along a lower edge 610 of the flexure structure 600, and inner parts 604 disposed between the upper edge 608 and the lower edge 610. Elastic arms 606 can join the outer parts 602 to the inner parts 604 as generally shown in FIG. 6A.

FIG. 6B shows the flexure structure 600 in a stretched state. As shown, the elastic arms 606 can flex and thereby allow adjacent outer parts 602 and adjacent inner parts 604 to move apart from one another. The elastic arms 606 can be elastic and thus exert a force that tends to move adjacent outer parts 602 and adjacent inner parts 604 back to their original positions with respect to each other after the forces that stretched the flexure structure 600 are removed. The specific configuration and structure illustrated in FIGS. 6A and 6B of the flexure structure 600 is an example only, and the flexure structure 600 can alternatively comprise other configurations or structures. Indeed, the flexure structure 600 can comprise any configuration and structure that allows the flexure structure 600 to be stretched and imparts forces, when stretched, that tends to return the flexure structure 600 generally to its original pre-stretched position or configuration.

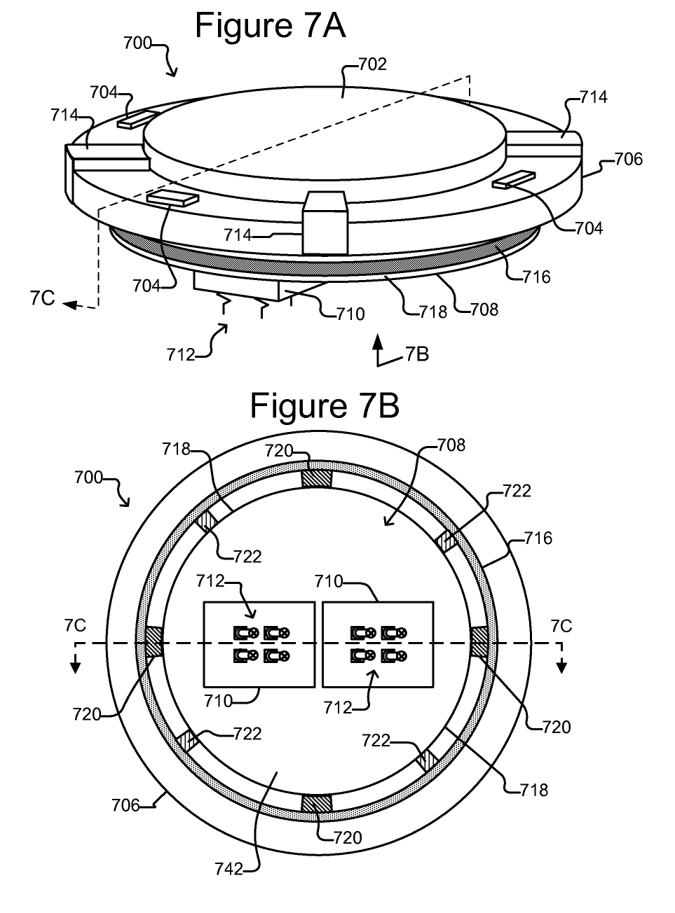

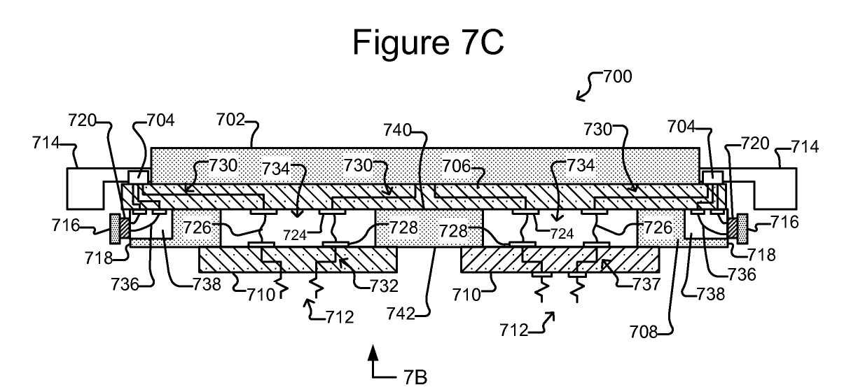

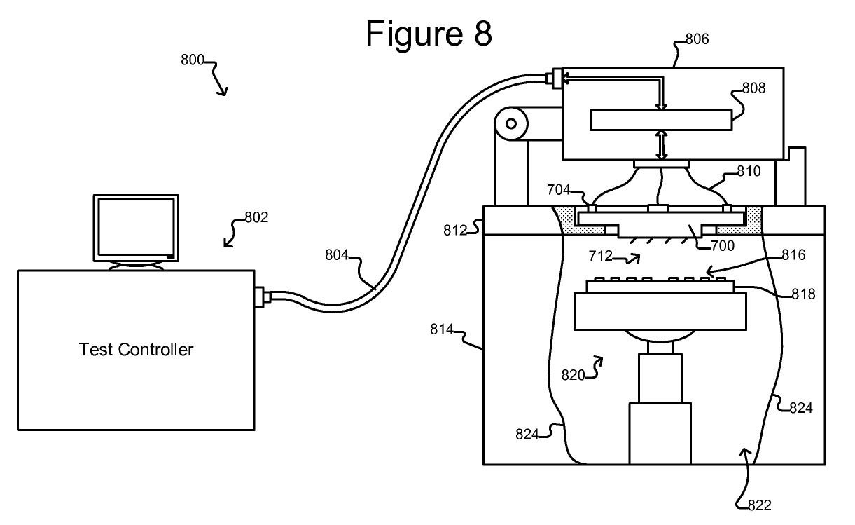

As mentioned, the contactor device 100 of FIGS. 1A, 1B, and 1C can be any type of contactor device. FIGS. 7A, 7B, and 7C illustrate a probe card assembly 700 that can be an example of the contactor device 100 of FIGS. 1A, 1B, and 1C. As will be seen, the probe card assembly 700 can include a stiffener structure 702, a wiring substrate 706, a stiffening frame 708, and probe substrates 710, which together can be an example of the support assembly 102 of FIGS. 1A, 1B, and 1C. The probe card assembly 700 can also include signal connectors 704 and probes 712 that can be examples of the signal connectors 106 and probes 108 of FIGS. 1A, 1B, and 1C. (Signal connectors 704 can be a non-limiting example of a signal interface.) The probe card assembly 700 can be used in a test system like the test system 800 of FIG. 8—which is discussed below—to test electronic devices such as semiconductor dies.

As shown, the probe card assembly 700 can include a wiring substrate 706 and one or more probe substrates 710. Signal connectors 704—which can be the same as or similar to the signal connectors 106 in FIGS. 1A, 1B, and 1C—can be located on the wiring substrate 706. Electrically conductive probes 712—which can be the same as or similar to the probes 108 in FIGS. 1A, 1B, and 1C—can be located on the one or more probe substrates 710. Electrical connections 730 (e.g., electrically conductive traces and/or vias) can be provided through the wiring substrate 706 to terminals 724 on the wiring substrate 706, which can be electrically connected by electrical connections 726 to terminals 728 on the probe substrates 710. As shown, the electrical connections 726 can pass through openings 734 in a stiffening frame 708. Electrical connections 732 (e.g., electrically conductive traces and/or vias) through the probe substrates 710 can electrically connect the terminals 728 and the probes 712. In some embodiments, the wiring substrate 706 can be a semi-rigid substrate (e.g., a printed circuit board) suitable for supporting the signal connectors 704 and providing the electrical connections 730 to the terminals 724. The electrical connectors 726 can comprise any suitable electrical connections for electrically connecting the terminals 724 and the terminals 728 including without limitation wires or an interposer. In some embodiments, the probe substrates 710 can be a rigid substrate (e.g., a multilayer ceramic wiring substrate).

As also shown in FIGS. 7A, 7B, and 7C, the probe card assembly 700 can also include a stiffener structure 702 and a stiffening frame 708. The stiffener structure 702 and the stiffening frame 708 can be rigid structures (e.g., comprising metal or another rigid material) and can thus impart rigidity to the probe card assembly 700. The stiffener structure 702, the stiffening frame 708, and the probe substrates 710 can be coupled to each other. For example, the probe substrates 710 can be directly coupled to the stiffening frame 708, which can be directly coupled to the stiffening structure 702. Any mechanisms suitable for coupled such structures can be used to couple the stiffener structure 702, stiffening frame 708, and the probe substrates 710 to each other. For example, bolts, screws, clamps, etc. can be used. As shown in FIGS. 7A, 7B, and 7C, the wiring substrate 706 can be disposed between the stiffener structure 702 and the stiffening frame 708. As also shown, the stiffener structure 702 can include extensions 714, which, as will be seen, can be physically coupled to—and thus be the means by which the probe card assembly 700 is coupled to—a test system. The stiffener structure 702 can thus not only stiffen the probe card assembly 700 but can also be a means by which the probe card assembly 700 can be coupled to a test system.

As also shown in FIGS. 7A, 7B, and 7C, the probe card assembly 700 can include a flexure band 716, which can be stretched around a peripheral edge 718 of the stiffening frame 708. The flexure band 716 can be the same as or similar to the flexure band 104 in FIGS. 1A, 1B, and 1C, including any of the flexure bands 200, 300, or 400 as shown in FIGS. 2, 3, 4, 5, 6A, and 6B. For example, like the flexure band 104, in some embodiments, the flexure band 716 can be relatively thin so that it protrudes relatively little from the peripheral edge 718 of the frame 708. For example, in some embodiments, the flexure band 716 can be less than 3000 microns thick or even less than 1500 microns, 750 microns, or 350 microns thick. In other embodiments, however, the flexure band 716 can be more than 3000 microns thick.

As shown in FIGS. 7B and 7C, one or more temperature control devices 720 and/or one or more temperature sensing devices 722 (see FIG. 7C) can be located between the peripheral edge 718 of the stiffening frame 708 and the flexure band 716, which can thus hold the temperature control devices 720 and/or temperature sensing devices 722 against the peripheral edge 718 of the stiffening frame 708. The peripheral edge 718 can connect a first surface 740 and a second surface 742 of the stiffening frame 708, which as best seen in FIG. 7C, can include spaces 738 for electrical connections 736 (e.g., electrically conductive traces, vias, wires, etc.) to the temperature control devices 720 and/or the temperature sensing devices 722. The electrical connections 736 and electrical connections 730 through the wiring substrate 706 can connect the temperature control devices 720 and/or the temperature sensing devices 722 to the signal connectors 704. The temperature control devices 720 can thus be controlled by control signals provided through the signal connectors 704 and the electrical connections 730 and 736, and signals from the temperature sensing devices 720 that are a function of a sensed temperature can thus be provided through the electrical connections 730 and 736 and the signal connectors 704.

The probe card assembly 700 illustrated in FIGS. 7A, 7B, and 7C is an example only, and variations are possible. For example, a flexure band like the flexure band 716 can alternatively or in addition be stretched around a peripheral edge of the stiffener structure 702, the wiring substrate 708, and or one or more of the probe substrates 710. Such a flexure band or bands can hold temperature control devices like the temperature control devices 720 and/or temperature sensing devices like the temperature sensing devices 722 against the peripheral edge of the stiffener structure 702, the wiring substrate 708, and/or the probe substrates 710. As another example, the flexure band 716 itself can be a temperature control device and/or a temperature sensing device. For example the flexure band 716 can be a resistive heating device. In such a case, the probe card assembly 700 need not include the temperature control devices 720, and the electrical connections 736 can be connected to the flexure band 716 to control the temperature of the flexure band 716. As another example, the probe card assembly need not include the temperature sensing devices 722, or the temperature sensing devices 722 can be in locations other than between the flexure band 716 and the peripheral edge 718 of the frame 708. In fact, as generally discussed above with respect to the flexure band 104, the resistance of the flexure band 716 can be measured and changes in the measured resistance can indicate changes in the temperature of the flexure band 716. The flexure band 716 can thus itself be a temperature sensing device. As yet another example, certain numbers of the signal connectors 704, the extensions 714, the electrical connections 730, 726, and 732, the terminals 724 and 728, the probe substrates 710, the temperature control devices 720, the temperature sensing devices 722, and the probes 712 are shown in FIGS. 7A, 7B, and 7C. The probe card assembly 700 can, however, have different numbers of those elements.

As mentioned, the probe card assembly 700 of FIGS. 7A, 7B, and 7C can be used to test electronic devices. FIG. 8 illustrates an example of a test system 800 in which the probe card assembly 700 can be used to test DUT 818. The acronym “DUT” can mean “device or devices under test,” which can be any electronic device or devices including without limitation semiconductor dies (singulated or in wafer form, packaged or unpackaged). As shown, the test system 800 can include a test controller 802, which can provide input signals to the DUT 818 and can receive response signals generated by the DUT 818 in response to the input signals. The term “test signals” can refer generically to either or both the input signals generated by the test controller 802 and the response signals generated by the DUT 818 in response to the input signals. The probe card assembly 700 can be coupled to a mounting structure 812 (e.g., a head plate or insert ring) of a housing 814 (e.g., a prober) of the test system 800. The probes 712 of the probe card assembly 700 can make pressure-based electrical connections with terminals 816 of the DUT 818, and the test signals can be passed between the test controller 802 and the DUT 818 through a connection 804 (e.g., a coaxial cable, a wireless link, a fiber optic link, etc.), electronics 808 in a test head 806, signal connectors 810 between the test head 806 the probe card assembly 70, and the probe card assembly 700. As shown, the signal connectors 810 can be connected to the signal connectors 704 of the probe card assembly 700.

As shown, the probe card assembly 700 can be coupled to the mounting structure 812 of the housing 814. For example, the extensions 714 of the stiffener structure 702 (see FIGS. 7A, 7B, and 7C) can be coupled (e.g., bolted, clamped, etc.) to the mounting structure 812. As shown, the housing 814 can include a moveable chuck 820 on which the DUT 818 is disposed. The chuck 820 can be located in an interior 822 of the housing 814, which is shown in FIG. 8 with a cutout 824 to make part of the interior 822 visible in FIG. 8. The chuck 820 can move the DUT 818 such that terminals 816 of the DUT 818 are pressed against probes 712 of the probe card assembly 700. Alternatively or in addition, the probe card assembly 700 can be moved. With pressured-based electrical connections between the probes 712 and the terminals 816, there are a plurality of electrical paths (or communications channels) between the test controller 802 and the terminals 816 of the DUT 818. Such electrical paths (or communications channels) can be through the communications link 804, the test head 806 (including electronics 808), the connectors 810 and connectors 704, the probe card assembly 700 (including electrical connections 730, 726, and 732 shown in FIG. 7C), and the probes 712.

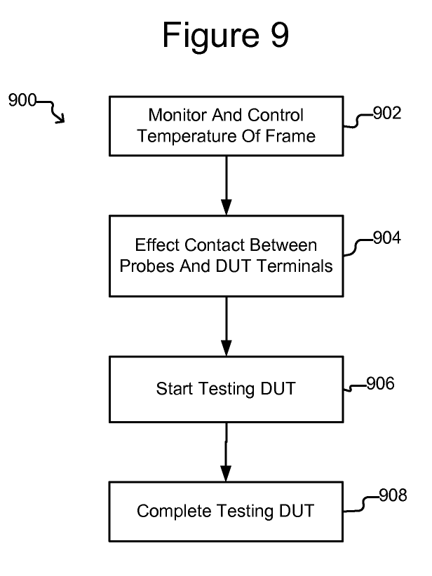

FIG. 9 illustrates an example of a process 900 that can be implemented using the test system 800 of FIG. 8 to test the DUT 818. Although the process 900 of FIG. 9 is not limited to being implemented on the test system 800 of FIG. 8, for ease of discussion and illustration, the process 900 is discussed herein as implemented on the test system 800.

Initially, the probe card assembly 700 can be coupled to the mounting structure 812, and the DUT 818 can be placed on the chuck 820 as shown in FIG. 8. Optionally, the probe card assembly 700 or one or more components of the probe card assembly 700 can be heated or cooled to a desired temperature prior to coupling the probe card assembly 700 to the mounting structure 812. For example, the stiffening frame 708 can be heated or cooled to a desired temperature by the temperature control devices 720 prior to coupling the probe card assembly 700 to the mounting structure 812. Thermal insulating properties of the flexure band 716 can help maintain the stiffening frame 708 at the desired temperature while the probe card assembly 700 is being coupled to the mounting structure 812.

Referring now to the process 900 of FIG. 9, the temperature of the stiffening frame 708 can be monitored and/or controlled at 902 of the process 900. As discussed above and illustrated in FIGS. 7A, 7B, and 7C, the probe card assembly 700 can include the flexure band 716 stretched around the peripheral edge 718 of the stiffening frame 708. As also discussed above, the flexure band 716 can hold one or more temperature control devices 720 and/or one or more temperature sensing devices 722 against the peripheral edge 718 of the stiffening frame 708. As also discussed above, alternatively, the flexure band 716 itself can be a temperature control device. At 902 of the process 900 of FIG. 9, the test controller 802 can receive from the temperature sensing devices 722 (and/or the flexure band 716 if the flexure band 716 is a temperature sensing device) signals (e.g., electrical signals) indicating the temperature of the stiffening frame 708. Such signals can be provided to the test controller 802 through the electrical connections 736 and 730, the signal connectors 704 and 810, the test head 806, and the communications link 804. (See FIGS. 7A, 7B, 7C, and 8.) At 902 of the process 900 of FIG. 9, the test controller 802 can alternatively or also provide control signals (e.g., electrical signals) to the temperature control devices 720 (or the flexure band 716 if the flexure band 716 is a temperature control device) to control the temperature of the temperature control devices 720 and thus the temperature of the stiffening frame 708. Such control signals can be provided from the test controller 802 through the communications link 804, the test head 806, the signal connectors 810 and 704, and the electrical connections 730 and 736 to the temperature control devices 720. (See FIGS. 7A, 7B, 7C, and 8.) Alternatively, rather than the test controller 802, another device (not shown) can be connected to the temperature control devices 720 and the temperature sensing devices 722.

In some embodiments, the temperature control devices 720 (and/or the flexure band 716 if the flexure band 716 is a temperature control device) and the temperature sensing devices 722 (and/or the flexure band 716 if the flexure band 716 is a temperature sensing device) can be used to keep the thermal strain of the DUT 818 and the stiffening frame 708 the same or substantially the same. Substantially the same can mean that the thermal strain of the DUT 818 and the thermal strain of the stiffening frame 708 are close enough in value that the probes 712 stay sufficiently aligned with the terminals 816 of the DUT 818 to remain in contact with the terminals 816 even as the DUT thermally expand or contract during testing. The thermal strain of the DUT 818 is as follows: CTE_{DUT}*ΔT_{DUT}, where CTE_{DUT} is the coefficient of thermal expansion of the DUT 818, * means multiplication, and ΔT_{DUT} is the difference between the actual temperature of the DUT 118 at any given time during testing of the DUT 818 with the probe card assembly 700 and a reference temperature. The thermal strain of the stiffening frame 708 is as follows: CTE_{frame}*ΔT_{frame}, where CTE_{frame} is the coefficient of thermal expansion of the stiffening frame 708; * means multiplication, and ΔT_{frame} is the difference between the actual temperature of the stiffening frame 708 at any given time during use of the probe card assembly 700 and a reference temperature. In practice, the probe card assembly 700—and in particular the stiffening frame 708—can be configured such that the probes 712 align with the terminals 816 of the DUT 818 at a reference temperature, and thereafter the thermal strain of the DUT 818 and the thermal strain of the stiffening frame 708 can be made equal or approximately equal by controlling the temperature of the stiffening frame 708 during testing of the DUT 818 so that the thermal strain of the stiffening frame 708 is the same or substantially the same as the thermal strain of the DUT 818 over the range of temperatures of the stiffening frame 708 and the DUT 818 during testing of the DUT 818.

Alternatively or in addition, the temperature control devices 720 (and/or the flexure band 716 if the flexure band 716 is a temperature control device) and the temperature sensing devices 722 (and/or the flexure band 716 if the flexure band 716 is a temperature sensing device) can be used to keep the thermal strain of the stiffening frame 708 the same or substantially the same as the thermal strain of the probe substrates 710 during testing of the DUT 810. For example, the foregoing can be used to keep electrical connections between the electrical connections 726 and the terminals 728 (see FIG. 7C) sufficiently aligned to maintain the electrical connections between the electrical connections 726 and the terminals 728 even as the temperature of the stiffening frame 708 and/or the probe substrates 710 change. Again, the phrase sufficiently the same when used with regard to thermal strains can mean sufficiently close in value to maintain such electrical connections over the expected operating temperature range during testing of the DUT 818.

At 904 of the process 900 of FIG. 9, terminals 816 of the DUT 818 can be brought into contact with probes 712 of the probe card assembly 700. This can be accomplished by moving the chuck 820 such that terminals 816 of the DUT 818 are pressed against probes 712 of the probe card assembly 700. Alternatively, the probe card assembly 700 can be moved, or both the chuck 820 and the probe card assembly 700 can be moved to effect contact between the terminals 816 and the probes 712.

As mentioned above, temporary, pressure-based electrical connections can thus be established between terminals 816 of the DUT 818 and probes 712. Then, at 906 of the process 900 of FIG. 9, testing of the DUT 818 can be started. The DUT 818 can be tested by providing test signals (which, as discussed above, can include input signals generated by the test controller 802, and response signals generated by the DUT 818 in response to the input signals) between the test controller 802 and the DUT 818 through the communication link 804, test head 806, connectors 810 and 704, and the probe card assembly 700. The test controller 802 can analyze the response signals generated by the DUT 818 to determine whether the DUT 818 passes the testing in whole or in part. For example, the test controller 802 can compare the response signals to expected response signals. If the response signals match the expected response signals, the test controller 802 can determine that the DUT 818 (or part of the DUT 818) passed the testing. Otherwise, the test controller 802 can determine that the DUT 818 (or part of the DUT 818) failed the testing. As another example, the test controller 802 can determine whether the response signals are within acceptable ranges, and if so, can determine that the DUT 818 (or part of the DUT 818) passed the testing.

The monitoring and controlling of the temperature of the stiffening frame 708 at 902 of the process 900 of FIG. 9 can continue through the effecting contact at 904 and the testing at 906 of the process 900 of FIG. 9 until testing of the DUT 818 is completed at 908 of the process 900. As mentioned above, the DUT 818 can comprise a plurality of semiconductor dies, which can be dies that are unsingulated from the wafer on which the dies were made or dies that have been singulated from the wafer on which the dies were made. If the dies are unsingulated, after the testing is completed at 908 of the process 900 of FIG. 9, the dies can be singulated from the wafer. The dies that passed the testing can be shipped to customers and/or incorporated into products. The process 900 of FIG. 9 can thus be a process that produces tested semiconductor dies.

The test system 800 of FIG. 8 and the process 900 of FIG. 9 are examples only, and variations are possible. For example, the monitoring and controlling of the temperature of the stiffening frame 708 at 902 of the process 900 of FIG. 9 can alternatively start after effecting contact at 904 or after starting testing at 906 of the process 900 of FIG. 9. As another example, the contactor device 100 of FIGS. 1A, 1B, and 1C can be used in the test system 800 in place of the probe card assembly 700. As another example, as mentioned above, a flexure band like the flexure band 716 can alternatively or in addition be stretched around a peripheral edge of the stiffener structure 702, the wiring substrate 708, and or the probe substrates 710. Such a flexure band or bands can hold temperature control devices like the temperature control devices 720 and/or temperature sensing devices like the temperature sensing devices 722 against the peripheral edge of the stiffener structure 702, the wiring substrate 708, and or the probe substrates 710. In such embodiments, the temperature control devices (and/or the flexure band if the flexure band is a temperature control device) and the temperature sensing devices (and/or the flexure band 716 if the flexure band 716 is a temperature sensing device) can be used to keep the thermal strain of the component about which the flexure band is stretched the same or substantially the same as the thermal strain of another component of the probe card assembly 700.

Some embodiments of the flexure band disclosed herein can provide one or more advantages. For example, utilizing a flexure band (e.g., 104 or 716) to hold one or more temperature control devices (e.g., 110 or 720) and/or temperature sensing devices against a peripheral edge (e.g., 114 or 718) of the a support assembly (e.g., 102) or a component (e.g., stiffening frame 708) of a support assembly can be less costly and/or reduce manufacturing complexities compared to building such temperature control or sensing devices into a support assembly or component of a support assembly. As another example, such a flexure band can simplify a process of replacing such temperature control or sensing devices. As yet another example, the flexure band (e.g., 104 or 716) can be made of a material and/or can be coated with a material that can reduce to a negligible level contamination (e.g., by out gassing) given off by the band and/or impart desired specific thermal properties (e.g., specific heat, thermal conductivity, and/or thermal diffusivity). As still another example, a flexure band (e.g., 10-4 or 716) can be made of a material and/or can be coated with a material that can allow the flexure band to maintain desired mechanical properties (e.g., elasticity or pressure generated while stretched) at consistent values over a given operating temperature range more advantageously than other types of bands such as rubber bands. As a still further example, an elastic flexure band (e.g., 104 or 716) can be more advantageous than an inelastic band (e.g., a metal “C” clamp). Due to inelasticity, a “C” clamp tends to loosen from a component about which the “C” clamp is tightened if the “C” clamp and the component expand or contract due to different coefficients of thermal expansion and a change in operating temperature.

As still further examples, although the flexure bands disclosed herein are discussed with regard to use in a contactor device or probe card assembly, the flexure bands can alternatively be used in other applications. For example, the flexure bands can be used with medical devices, electronic devices, or other such devices to hold components of the devices together and/or to hold instruments like temperature control instruments or temperature sensing instruments against the devices.

1. A probe card assembly comprising:
a signal interface configured to connect to a test controller for controlling testing of semiconductor dies;
a plurality of electrically conductive probes configured to contact terminals of the semiconductor dies, wherein the probes are electrically connected to the signal interface;
a support assembly on which the signal interface and the probes are disposed;
a temperature control device disposed at a peripheral edge of a component of the support assembly; and
a flexure band stretched around the peripheral edge of the component of the support assembly.

2. The probe card assembly of claim 1, wherein the flexure band comprises one or more materials that outgas negligible levels contaminants.

3. The probe card assembly of claim 1 further comprising a plurality of temperature control devices disposed around the peripheral edge of the component of the support assembly, wherein the temperature control devices are disposed between the flexure band and the peripheral edge.

4. The probe card assembly of claim 3 further comprising a plurality of temperature sensing devices disposed around the peripheral edge of the component of the support assembly, wherein the temperature sensing devices are disposed between the flexure band and the peripheral edge.

5. The probe card assembly of claim 4, wherein:
the component of the support assembly comprises a stiffening frame with a first surface and an opposite second surface, the peripheral edge connecting the first surface and the second surface,
the support assembly comprises a probe substrate on which ones of the probes are disposed, and
the probe substrate is coupled to the second surface of the frame.

6. The probe card assembly of claim 1, the flexure band is the temperature control device, and the flexure band is electrically connected to the signal interface.

7. The probe card assembly of claim 1, wherein the flexure band comprises a plurality of elastic structures.

8. The probe card assembly of claim 7, wherein each of the elastic structures comprises a plurality of parts disposed along the face of the band and interlinked by elastic arms, wherein stretching the band causes the elastic arms to flex allowing ones of the parts to move away from others of the parts.

9. The probe card assembly of claim 1, wherein the band comprises stainless steel.

10. The probe card assembly of claim 1, wherein the band comprises a thermal insulating material disposed on the metal to impede a flow of heat between the component of the support assembly and surroundings of the component.

11. A method of producing a tested semiconductor die, the method comprising:
obtaining a probe card assembly comprising a support assembly on which are disposed a signal interface to a test controller for controlling testing of semiconductor dies and a plurality of electrically conductive probes configured to contact terminals of the semiconductor dies, wherein the probes are electrically connected through the probe card assembly to the interface, the probe card assembly further comprising a flexure band stretched around a peripheral edge of a component of the support assembly;
controlling a temperature control device disposed at the peripheral edge of the component of the support assembly, wherein the temperature control device is held against the peripheral edge by the flexure band;
effecting contact between ones of the probes and ones of terminals of the dies; and
testing said dies by providing test signals between the ones of the terminals and the ones of the probes through the probe card assembly.

12. The method of claim 11, wherein the flexure band comprises one or more materials that outgas negligible contaminants.

13. The method of claim 11 further comprising monitoring a temperature of the component of the support assembly utilizing at least one temperature sensing device disposed at the peripheral edge of the component of the support assembly between the flexure band and the peripheral edge, wherein the controlling further comprises controlling a temperature of at least one temperature control device disposed at the peripheral edge of the component of the support assembly between the flexure band and the peripheral edge.

14. The method of claim 13, wherein:
the component of the support assembly comprises a stiffening frame with a first surface and an opposite second surface, the peripheral edge being between the first surface and the second surface,
the support assembly comprises a probe substrate on which ones of the probes are disposed, and
the probe substrate is coupled to the second surface of the frame.

15. A flexure band comprising:
a plurality of elastic metal structures disposed in an interconnected continuous loop forming a band with an outer face and an inner face.

16. The flexure band of claim 15 further comprising a thermal insulating material disposed on the outer face of the band.

17. The flexure band of claim 15, wherein the entire band consists of the elastic metal structures.

18. The flexure band of claim 15 further comprising non-elastic metal structures disposed between ones of the elastic metal structures, wherein the band comprises the elastic metal structures and the non-elastic metal structures.

19. The flexure band of claim 15, wherein each of the elastic structures comprises a plurality of parts disposed along the face of the band and interlinked by elastic arms, wherein stretching the band causes the elastic arms to flex allowing ones of the parts to move away from others of the parts.

20. The flexure band of claim 15, wherein the band comprises stainless steel.

21. The flexure band of claim 15, wherein the flexure band comprises one or more materials that outgas negligible levels contaminants.

22-42. (canceled)
